(19) United States
(12) Patent Application Publication
(10) Pub. No.: US 2002/0189089 A1
(43) Pub. Date: Dec. 19, 2002

(54) Mounting electrical devices to circuit boards

(76) Inventors: Anthony G Matterson, Hertfordshire (GB); Jonathan N Hill, Hertfordshire (GB)

Correspondence Address: Nixon & Vanderhye, 8th Floor, 1100 North Glebe Road, Arlington, VA, 22201-4714, US

(21) Appl. No.: 10/149,151

(22) PCT Filed: Dec. 8, 2000
(86) PCT No.: PCT/GB00/04678

(30) Foreign Application Priority Data
Dec. 9, 1999 (GB) 99291684

(51) Int. Cl. H05K 3/30; B23P 19/00

(52) U.S. Cl. 29/832; 29/739; 29/760

(57) ABSTRACT

Described herein is an improved mounting arrangement for mounting an electrical device (13) on a circuit board (9). The mounting arrangement comprises a substrate (12) which is spaced from the circuit board (9) by a support (14) which incorporates a heat sink (16). A clamp (17) forces one end of the substrate (12) against the support (14) to provide a mechanically stable arrangement which has improved thermal contact with the heat sink (16).

This invention relates to apparatus for, and a method of mounting electrical devices to circuit boards.

The present invention arose during the development of a high performance digital signalling processing apparatus for a communications satellite. The invention was prompted by the conflicting constraints associated with such an application. The processing apparatus needed to be mechanically robust to survive launch and the harsh environment of space. Volume and mass are at a premium in a satellite, so the electrical devices making up the processing apparatus needed to be both lightweight and of a small size. However, the mounting of thermally dissipative electrical devices, such as ASICs, in a confined space gives rise to temperature control problems. Low thermal efficiency can drastically limit the lifetime of the processing apparatus and hence the satellite.

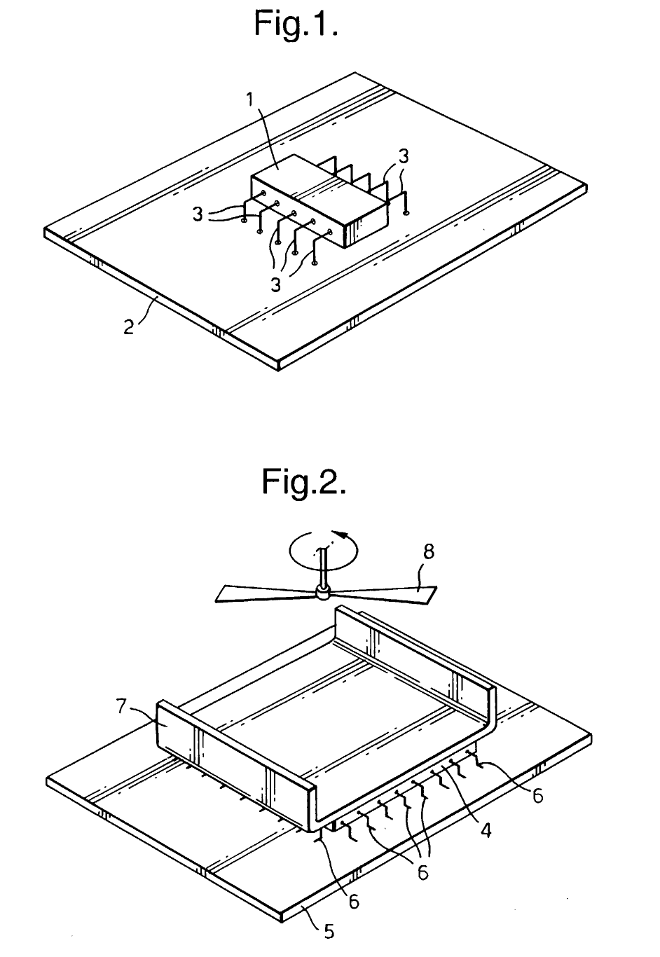

Conventional arrangements for mounting electrical devices to circuit boards have been found to solve some, but not all of these problems. For example, FIG. 1 shows an electrical device 1 mounted to a printed wiring board 2 by means of electrical conductors 3 extending from the sides of the device. The conductors 3 provide both electrical connection between the device and the board and mechanical support for the device. However, this scheme only works well for low mass devices and for those not requiring thermal control. There is a risk that differential thermal expansion between the device 1 and the board 2 may induce damaging stress.

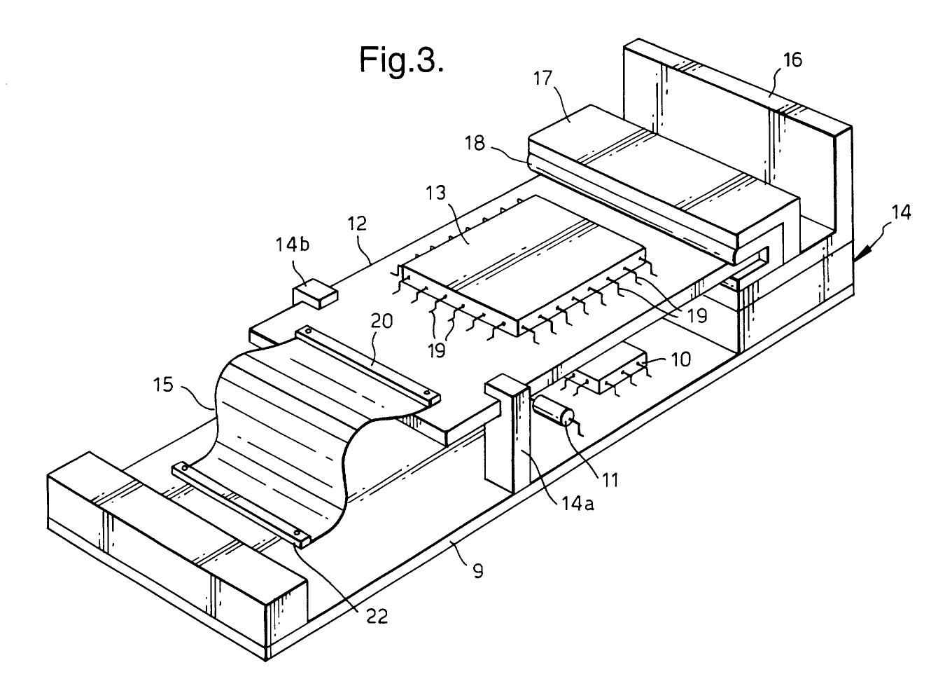

In the case where thermal control is required, a scheme such as that illustrated in FIG. 2 may be employed. In this scheme, a device 4 is mounted to a circuit board 5 via conductors 6 as before. Heat from the device is transferred to a thermal spreader or finned aluminium block 7. A small, electrically driven fan 8 is installed adjacent the spreader to remove beat into an ambient fluid such as air. However, this scheme occupies a high volume, is relatively complex to install and is dependent on the reliable operation of the fan.

The invention provides apparatus for mounting an electrical device to a circuit board comprising a substrate arranged to carry the device and a support for the substrate, the support being arranged to space the substrate from the board.

The provision of a support for the substrate provides mechanical stability; the space between the substrate and the board allows for the mounting of more electrical devices in a given volume than was hitherto achievable.

According to a second aspect of the invention, the substrate is thermally conductive and at least part of the support comprises a heat sink for rejection of heat from the electrical device via the substrate.

The substrate and support together provide a thermal path to enable the electrical device to reject heat more efficiently than hitherto.

Advantageously, a clamp is provided in order to hold a first end portion of the substrate against a region of the support. This arrangement provides extra mechanical stability and good thermal contact between the substrate and the support. Preferably a thermally conductive filler is provided between the clamp and the end portion of the substrate to provide even better thermal contact.

Advantageously, the arrangement allows for relative lateral movement between the substrate and a region of the support. This is to ensure that the substrate is not overly stressed during mechanical vibration of the apparatus such as would be encountered during launch of a satellite.

Electrical connections between the substrate and the circuit board may be provided by a flexible electrical conductor or a flexible, electrically conductive substrate.

Preferably the substrate includes aluminium nitride which has superior thermal conductivity.

In an alternative arrangement, the support may be arranged to support a substrate having at least one pre-mounted electrical device.

The invention further provides a method of mounting an electrical device to a circuit board, comprising connecting the device to a substrate and supporting the substrate on a support arranged to space the substrate from the circuit board.

The invention will now be described, by way of example, with reference to the accompanying drawings, in which:

FIG. 1 illustrates schematically a prior art arrangement for mounting an electrical device to a circuit board;

FIG. 2 illustrates schematically a further prior art arrangement for mounting an electrical device to a circuit board;

FIG. 3 illustrates schematically apparatus constructed according to the invention;

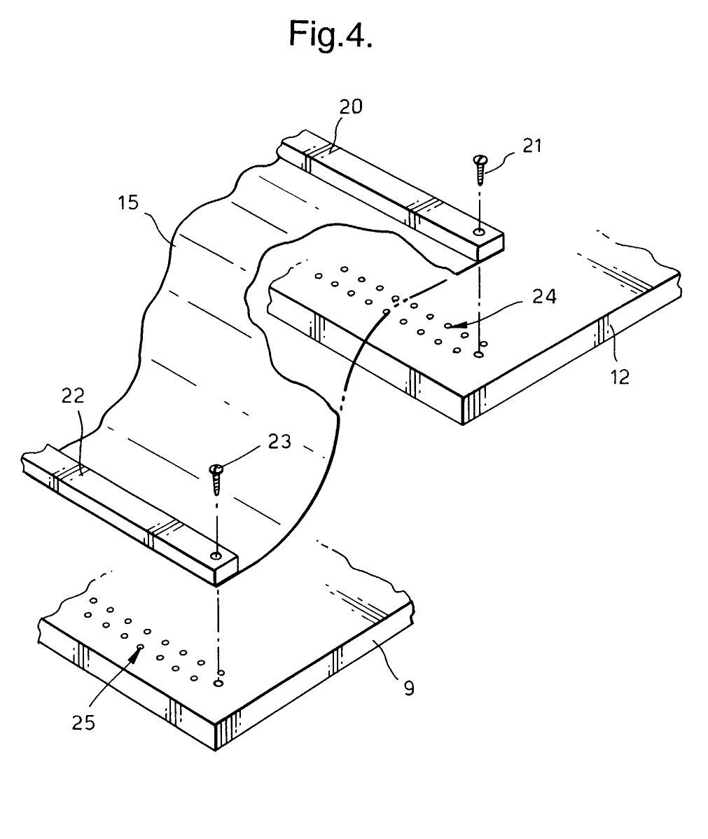

FIG. 4 is a partly exploded perspective view of the electrical link between the substrate and the board of FIG. 3;

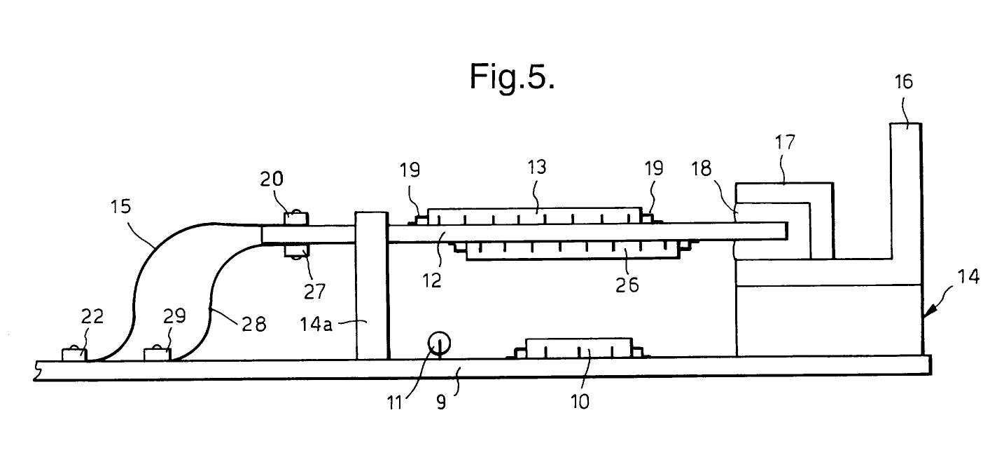

FIG. 5 is a side view of an alternative embodiment of the invention; and

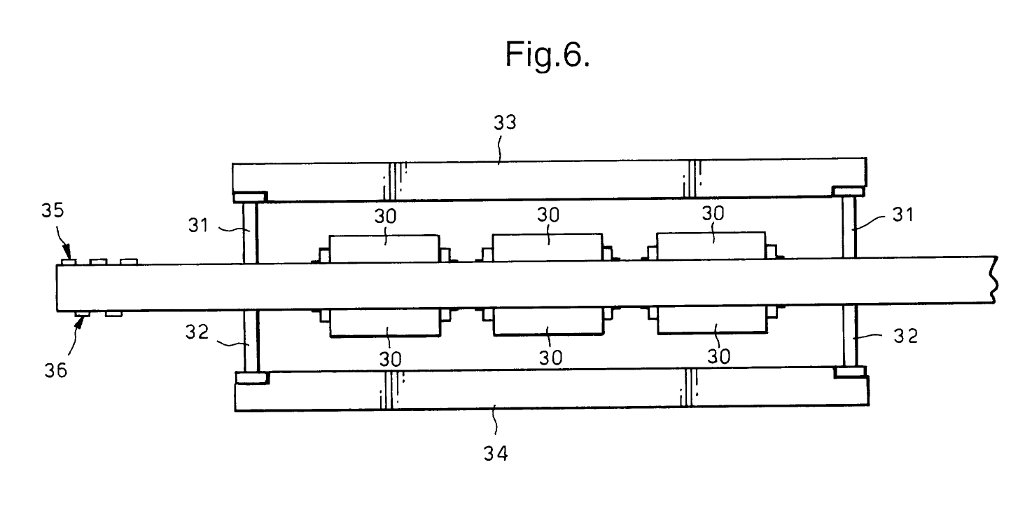

FIG. 6 is a sectional view of apparatus constructed according to another aspect of the invention.

Like reference numerals have been given to like parts throughout the specification.

Referring to FIG. 3, a circuit board 9 is shown having electrical devices 10, 11 mounted on it in a conventional manner, such as that shown in FIG. 1. In accordance with the invention a substrate 12 is provided on to which electrical devices such as a multichip module (MCM) 13 may be mounted, the substrate being spaced from a circuit board 9. An MCM comprises a plurality of electrical devices. Complex processing functions can be implemented with groups of electrical devices, each performing a sub-set of the friction.

In these circumstances, it is more efficient to connect these devices within a single hermetic package known as an MCM. The multichip module, or other electrical device, may be mounted to the substrate in a conventional manner. A support 14 spaces the substrate 12 from the circuit board 9.

The multichip module 13 is electrically connected to the circuit board 9 via interconnects embedded in the sub state 12 and a flexible connector 15, which is described in more detail later in this specification.

It will be appreciated that the present invention permits the mounting of many devices to a circuit board. Devices may be mounted on the upper surface of the substrate, the underside of the substrate and on the area of circuit board underneath the substrate.

As well as providing electrical connections for the device, the substrate 12 also provides a thermal path for heat dissipated from the MCM 13. A suitable material for the substrate is aluminium nitride because of its superior thermal conductivity. Heat is rejected through the substrate 12 and into a heat sink 16 on the support 14. This, in turn, may be placed in intimate contact with cooling pipes or chambers (not shown) which may include flowing coolant. The provision of a thermal path permits the MCM 13 to reject more heat than was hitherto possible. Thus, the MCM runs at a cooler temperature and the lifetime of the device is prolonged.

A clamp 17 is provided in order to urge an end portion of the substrate 12 against the support 14. In this manner, the arrangement becomes mechanically stable and thermal contact between the substrate 12 and the heat sink 16 is improved. A further improvement in thermal contact is achieved by the introduction of a thermally conductive filler 18 between the opposing faces of the clamp 17 and the upper and lower surfaces of the end portion of the substrate 12. The filler 18, being resilient, also permits a limited amount of movement of the substrate 12 in the z-direction as shown in this drawing. By allowing the substrate 12 to move slightly, damaging stresses can be avoided, particularly during launch of a satellite including this apparatus.

The support 14 further comprises side supports 14a, 14b. Each of the side supports 14a, 14b has a slot which engages with a side edge region of the substrate 12. The side supports 14a, 14b are arranged to engage with respective opposite side edge regions of the substrate. The side supports 14a, 14b provide further mechanical stability for the substrate 12 and are arranged to allow limited movement of the substrate in the x- and y-directions as shown in the drawing.

The means by which the substrate 12 is electrically connected to the circuit board 9 is shown in FIG. 4. The MCM 13 is electrically connected, by means of the conductors 19 extending from it, to interconnects (not shown) embedded in the substrate 12. Typically, there are fifteen layers of embedded interconnects, which are sometimes referred to as integrated interconnects. Such a substrate having embedded electrical interconnects is sometimes known as a co-fired ceramic.

The interconnects are arranged to terminate at an end portion of the substrate. Preferably, this is the opposite end portion to that supported by the support 14 and clamp 17 arrangement. In this manner, the mechanical structure and thermal path are separated from the electrical path.

The embedded interconnects terminate in a land grid array 24 on the surface of the end portion of the substrate 12. A pressure contact 20 having an array of conductor terminations (not shown) that correspond with the pattern of the land grid array 24, is affixed to the end portion of the substrate 12 such that its terminations are forced into intimate contact with the land grid array. A suitable pressure contact 20 is a CIN::APSE button type of connector. A suitable means of demountably affixing the pressure contact 20 to the substrate 12 would be screw fasteners 21 extending through the contact 20 and substrate 12.

The demountable pressure contact 20 is located at an end of a flexible connector 15. Typically this comprises in the region of 250 parallel adjacent electrical conductors. The other end of the flexible connector 15 terminates in another pressure contact 22 whose terminations are placed in intimate contact with a land grid array 25 on the circuit board. Screw fasteners 23 may be used to hold the pressure contact 22 against the circuit board 9. In this manner, the MCM 13 is electrically connected to the circuit board 9. The flexible connector 15 advantageously provides negligible stiffness and thermal conductivity.

An alternative embodiment of the invention is shown in FIG. 5. This embodiment makes better use of the space saving aspect of the invention. In this embodiment, MCMs 13, 26 are mounted to the substrate 12 on the upper and lower surfaces respectively of the substrate. One end portion of the substrate 12 provides the thermal link to a heat sink 16 as before, and is also supported mechanically by support 14 and clamp 17. The other end portion provides the electrical link. In this embodiment, the embedded electrical interconnects in the substrate terminate in two land grid arrays (not visible in this drawing), one on the upper surface of the substrate and the other on the underside of the substrate. Demountable pressure contacts 20, 27 are fixed to respective ones of the arrays and separate flexible connectors 15, 28 associated with the pressure contacts on the substrate provide an electrical link between the arrays on the substrate and contacts 22, 29 associated with respective sets of arrays at different locations on the circuit board.

Apparatus constructed according to an alternative aspect of the invention is shown in FIG. 6. In this embodiment, a plurality of integrated circuits (ICs) 30 have been pre-fixed, in a conventional manner, to the upper and lower surfaces of a substrate 12. The ICs 30 have been packaged hermetically as an MCM with an integrated substrate. The packaging comprises frames 31, 32, typically made from Kovar. The frames 31, 32 surround the ICs 30 on the upper and lower surfaces respectively of the substrate 12 leaving a region of substrate extending from the sides of the packaging. Each frame 31, 32 has been brazed to the corresponding surface of the substrate 12. If the MCM comprised ICs on just one surface of the substrate, the brazing process could set up damaging stresses in the substrate. However, the brazing process carried out on the opposite surface of the substrate serves to balance the pressure exerted on the substrate. Lids 33, 34 for the frames 31, 32, which may also be made of Kovar, are provided. This form of MCM package can be attached to a circuit board in exactly the same way as before: a thermal link and mechanical support is provided at one end portion of the exposed substrate, while the other end portion of the exposed substrate provides land grid arrays 35, 36 on the upper and lower surfaces respectively for electrical connection to a circuit board by means of demountable pressure contacts and flexible connectors (not shown in this drawing).

It has been found that, by employing the present invention, a processing means can be assembled that is 50% lighter, and has an operating temperature thirty degrees centigrade lower, than conventional apparatus.

A further advantage is that, should the MCM 13 or other electrical device be found to be faulty, the substrate carrying the faulty device may be simply removed and replaced by a substrate carrying a functioning device. This is much simpler compared with the prior art arrangements of devices having conductors soldered to the circuit board.

Land grid arrays may also be used to mount the MCMs, or in the case of the FIG. 6 embodiment the ICs making up the MCM, to the substrate in place of the electrical conductors extending from the sides of the device. In this manner, a further space saving can be achieved. A flexible substrate having embedded electrical interconnects may be substituted for the flexible electrical conductor 15 employed to connect the substrate to the circuit board.

In a further alternative, the support may be extended and arranged to support at least one other substrate suspended above that which has already been mounted to the circuit board. In this manner, a stacked arrangement can be made. By utilising this idea, electrical devices can be mounted into spaces of irregular and/or restricted size and shape. Further variations will be apparent to those skilled in the art.

1. Apparatus for mounting an electrical device to a circuit board comprising a substrate arranged to carry the device and a support for the substrate, the support being arranged to space the substrate from the board.

2. Apparatus as claimed in claim 1, in which the substrate is thermally conductive and at least part of the support comprises a heat sink for rejection of heat from the electrical device via the substrate.

3. Apparatus as claimed in claim 1 or claim 2, further comprising a clamp arranged to hold a first end portion of the substrate against a region of the support.

4. Apparatus as claimed in claim 3, further comprising a thermally conductive filler interposed between the engaging faces of the clamp and the end portion of the substrate.

5. Apparatus as claimed in any preceding claim, in which the support is arranged to permit relative lateral movement of the substrate.

6. Apparatus as claimed in any preceding claim, in which the substrate includes at least one electrical conductor, and the device is electrically connectable to the circuit board via the conductor.

7. Apparatus as claimed in claim 6, in which the conductor is embedded in the substrate.

8. Apparatus as claimed in claim 6 or 7, in which the conductor associated with the substrate is electrically connected to the circuit board by means of a flexible electrical conductor.

9. Apparatus as claimed in claim 6 or 7, in which the conductor associated with the substrate is electrically connected to the circuit board by means of a flexible, electrically conductive substrate.

10. Apparatus as claimed in any preceding claim, in which the substrate includes aluminium nitride.

11. Apparatus for mounting an electrical device carried on a thermally conductive substrate including an electrical conductor to a circuit board, comprising a support for the substrate, the support being arranged to space the substrate from the board.

12. Apparatus as claimed in claim 11, in which at least part of the support comprises a heat sink for rejection of heat from the electrical device via the substrate.

13. Apparatus as claimed in claim 11 or 12, further comprising a clamp arranged to hold a first end portion of the substrate against a region of the support.

14. Apparatus as claimed in claim 13, further comprising a thermally conductive filler interposed between the engaging faces of the clamp and the end portion of the substrate.

15. Apparatus as claimed in any one of claims 11 to 14, in which the support is arranged to permit relative lateral movement of the substrate.

16. Apparatus as claimed in any one of claims 11 to 14, in which the conductor associated with the substrate is electrically connected to the circuit board by means of a flexible electrical conductor.

17. Apparatus as claimed in any one of claims 11 to 14, in which the conductor associated with the substrate is electrically connected to the circuit board by means of a flexible, electrically conductive substrate.

18. Apparatus, substantially as hereinbefore described, with reference to, or as illustrated in, the accompanying drawings.

19. A circuit board including apparatus as claimed in any preceding claim.

20. A method of mounting an electrical device to a circuit board, comprising connecting the device to a substrate and supporting the substrate on a support arranged to space the substrate from the circuit board.

21. A method of mounting an electrical device carried on a substrate to a circuit board, comprising supporting the substrate on a support arranged to space the substrate from the circuit board.

22. A method as claimed in claim 20 or 21, further comprising clamping an end portion of the substrate against a region of the support.

23. A method as claimed in claim 23, further comprising introducing a filler between the engaging faces of the clamp and the end portion of the substrate.

24. A method as claimed in any one of claims 20 to 23, further comprising electrically connecting the device to the circuit board via a conductor associated with the substrate.

25. A method, substantially as hereinbefore described, with reference to, or as illustrated in the accompanying drawings.
